(19) United States
(12) Patent Application Publication
(10) Pub. No.: US 2014/0349155 A1
(43) Pub. Date: Nov. 27, 2014

(54) Method and Devices for Making Available Information for the Purpose of Performing Maintenance and Servicing of a Battery Unit

(71) Applicants: Robert Bosch GmbH, Stuttgart (DE); Samsung SDI Co., Ltd., Yongin-si (KR)

(72) Inventor: Christoph Brochhaus, Aachen (DE)

(73) Assignees: Robert Bosch GmbH, Stuttgart (DE); Samsung SDI Co., Ltd., Yongin-si (KR)

(21) Appl. No.: 14/281,473

(22) Filed: May 19, 2014

(30) Foreign Application Priority Data
May 22, 2013 (DE) 10 2013 209 426.4

(51) Int. Cl. G01R 31/36

(52) U.S. Cl. CPC G01R 31/3679
USPC 429/90; 702/63

(57) ABSTRACT

A method for making available information for the purpose of performing maintenance and servicing of a battery unit includes detecting and quantizing useful data of a battery unit and forming histograms which have frequencies of the occurrence of specific values of the individual quantized useful data items or values derived therefrom. In this context there is provision that at least one current and at least one aggregated histogram are formed and stored in a non-volatile memory. Furthermore, a data structure, a computer program, and a battery management system are specified which are configured to execute the method, as well as a battery and a motor vehicle whose drive system is connected to a battery of this type.

This application claims priority under 35 U.S.C. §119 to patent application no. DE 10 2013 209 426.4, filed on May 22, 2013 in Germany, the disclosure of which is incorporated herein by reference in its entirety.

### BACKGROUND

The disclosure relates to a method for making available information for the purpose of performing maintenance and servicing of a battery unit, wherein useful data of a battery unit are detected and quantized, and wherein histograms are formed which have frequencies of the occurrence of specific values of the individual quantized useful data items or values derived therefrom.

Furthermore, a data structure with such information is specified, as well as a computer program and a battery management system which are configured, in particular, for executing the method. Furthermore, a battery and a motor vehicle with a battery of this type are specified.

Electronic control devices are used nowadays in increasing numbers in the field of automobiles. Examples of this are engine control devices, ABS systems and airbags. For electrically driven vehicles a current focus of research is the development of high-performance battery packs with associated battery management systems, i.e. control devices, which are equipped with software for monitoring the functionality of the battery. Battery management systems ensure, inter alia, safe and reliable functioning of the battery cells and battery packs which are used. They monitor and control currents, voltages, temperatures, insulation resistances and further variables for individual cells and/or the entire battery pack. By using these variables it is possible to implement management functions which increase the service life, reliability and safety of the battery system.

DE 10 2010 031 337 A1 presents a method of determining the expected service life of battery cells. In order to determine the expected service life of battery cells, physical variables and/or the number of executions of processes which take place in the battery cells are determined for a plurality of operating cycles and the frequency of the occurrence of specific values of the physical variable and/or the frequency of the number of executions of at least one specific process are/is stored. As a result, cell defects can be detected early and prevented, and precise knowledge about the expected service life of the battery cell can be acquired.

### SUMMARY

In the case of a method according to the disclosure for making available information for the purpose of performing maintenance and servicing of a battery unit there is provision that at least one current histogram and an aggregated histogram are formed and stored in a non-volatile memory.

A history of the use of the battery is advantageously recorded and can be read out within the scope of warranty claims and used for the evaluation of the use of the battery, for example for determining the expected service life or the state of health (SOH) of the battery unit. In this context, histograms are formed, wherein the histograms of the individual quantized useful data items have assignable numbers of detections of the respective quantized useful data item or values derived therefrom.

Derived data can be used, for example, to denote relative frequencies or systematic shifts or weightings of the detections of the useful data which are suitable for increasing the informative power or comparison force of the detected useful data.

It is preferably possible to freely define how many current and how many aggregated histograms are to be formed. In addition it is preferably possible to define what level of aggregation the histograms have, i.e. how many histograms or driving cycles are combined to form an aggregated histogram.

The term “the quantization of the detected useful data” denotes that reference points are defined which respectively represent boundaries of intervals, and the detected useful data are assigned to the intervals. The intervals can be of different sizes here or be defined in a regular fashion. For example, a temperature value range between −40° C. and +80° C. can be defined and divided into intervals of 10° C., 5° C., 2° C. or 1° C., wherein during the division of the intervals, on the one hand, the memory requirement is taken into account and, on the other hand, the informative power of the detected useful data which are quantized in this way.

During the driving cycle, the histogram is preferably updated in the volatile memory. After the driving cycle, the histogram is written into a non-volatile memory of the control device. Such a non-volatile memory is, for example, what is referred to as an EEPROM (electrically erasable programmable read-only memory), i.e. a non-volatile electronic module whose stored information can be deleted electrically. Within the scope of warranty claims the histogram can be read out of the non-volatile memory of the control device and used to evaluate the use of the battery.

The current histogram can relate merely to the last driving cycle or generally to a defined number of the last driving cycles, for example to the last 2, 3, 4 or 5 driving cycles. However, there is preferably provision that the histograms are formed after each driving cycle and stored. A current histogram therefore comprises, for example, the frequencies of the occurrence of specific values of the individual quantized useful data items of the last driving cycle, i.e. from a start of the driving cycle to an end of the driving cycle, wherein the events which trigger the start and the end of the driving cycle can be, for example, charging pulses, a change of state of the battery from “operation” (drive) to “charge” (charge), evaluation of a signal “charging active” or else evaluation of a state of change at a terminal 15, i.e. the ignition positive. Likewise, the event which triggers the start and the end of the driving cycle can be defined by detection of the so-called battery balancing. The driving cycle can be defined, for example, in that it comprises a subsequent charging process or does not comprise the latter.

The aggregated histogram preferably has an aggregation level of 2 to 10 driving cycles. An aggregation level of 4 to 5 driving cycles is particularly preferred. It is possible to provide that the aggregated histogram comprises the values of the last driving cycle. However, there is preferably provision that the aggregated histogram comprises such driving cycles which are not included in the current histogram.

The histograms of the last driving cycles are stored in a detailed fashion, while driving cycles lying further in the past are stored in an aggregated fashion. As a result, information about the use of the battery in the immediate past is present in detailed form. Driving cycles lying further back are present in a combined fashion. As a result, additional analysis possibilities in the event of failures of batteries or in the event of warranty claims are made available, in contrast to methods which store only one histogram.

According to one preferred embodiment, a total histogram is formed. A total histogram can be formed as an aggregated histogram over all the preceding driving cycles. There is preferably provision that the total histogram is formed by such driving cycles which are not included in the aggregated histograms and the current histogram.

The total histogram is particularly advantageously suitable for determining the service life and the state of health and aging state of the battery unit. In the total histogram, conclusions can be drawn about the average use per driving cycle by using a counter for the driving cycles. This gives an overview of the use of the battery during the previous total service life.

A detection rate of the useful data of the battery unit preferably has a defined value between 6/s and 6/h, preferably between 1/s and 1/min, particularly preferably 6/min or 1/min. After the defined time intervals, for example the current temperature and the current voltage of the cells is noted in the histogram. For measured values such as the temperature and the SOC it is possible for further preferred sampling rates to be between 1/m and 6/h. For voltages a filtered value is preferably stored, for example a mean value over a defined time period, wherein preferred time periods are also approximately 1 min. The detection rate of the respective useful data of the battery unit is preferably in a range which assists on-board diagnostics (OBD).

The useful data of the battery comprise, for example, the temperature, the state of charge, a current which is output or voltages which are made available. Likewise, variables derived therefrom can be included, for example variables which are integrated over time, variables which are multiplied with one another or aggregated in some other way such as, for example, the so-called state of health (SOH) of the battery in suitable quantified units. Furthermore, difference values between minimum and maximum states, for example states of charge, relative battery powers or number of executions of charging cycles and discharging cycles can be included in the useful data.

According to one preferred embodiment, the histograms are stored in a stack data structure. The stack data structure comprises, for example, the current histograms on the surface, the aggregated histograms at a lower level and the total histogram at the bottom of the data structure. If the data structure is filled with new values, this preferably takes place from top to bottom. The refreshing, i.e. updating of the stored histograms, and/or the aggregation of the lower layers can be implemented by, for example, programming close to the machine with the result that it takes place more quickly and less computationally intensively.

According to the disclosure, a data structure is also proposed with information on conditions of use of a battery, wherein the data structure was produced during execution of one of the methods described above. The data structure is read out, for example, by a computer device for the purpose of performing maintenance and servicing. The data structure comprises, for example, a first designator num_aggHisto, which specifies how many aggregated histograms are stored. The data structure comprises, for example, a second designator grad_aggHisto which indicates what level of aggregation the histograms are intended to have. The data structure comprises, for example, a further designator num_vollstHisto which can specify the number of complete histograms of the last driving cycle.

According to the disclosure, a computer program is also proposed according to which one of the methods described above here is carried out when the computer program is run on a programmable computer device. The computer program can be, for example, a module for implementing a device for making available information for the purpose of performing maintenance and servicing of a battery unit and/or a module for implementing a battery management system of a vehicle. The computer program can be stored on a machine-readable storage medium, for example on a permanent or re-writable storage medium or in an assignment to a computer device, for example on a portable memory such as a CD-ROM, DVD, a USB stick or a memory card. Additionally or alternatively to this the computer program can be made available for downloading on a computer device such as, for example, on a server or a cloud server, for example via a data network such as the Internet or a communications link such as, for example, a telephone line or a wireless connection.

According to the disclosure, a battery management system (BMS) is also made available having a unit for detecting useful data of a battery unit, a unit for quantizing the detected useful data and a unit which is configured to form at least one current histogram and at least one aggregated histogram, wherein the histograms have frequencies of the occurrence of specific values of the individual quantized useful data items or values derived therefrom.

According to the disclosure, a battery, in particular a lithium-ion battery or a nickel-metal hydride battery is also made available which comprises a battery management system and can be connected to a drive system of a motor vehicle, wherein the battery management system is, as described above, designed and/or configured to carry out the method according to the disclosure. The terms “battery” and “battery unit” in the present description are used in a way which is adapted to the customary usage for an accumulator or accumulator unit. The method can be applied to lithium-ion batteries as well as nickel-metal hydride batteries. The method is preferably used on a plurality of the cells, and in particular on all of the cells, of one or more batteries which are operated essentially simultaneously.

The battery preferably comprises one or more battery units which can comprise a battery cell, a battery module, a module train or a battery pack. The battery cells are preferably combined spatially here and connected to one another by means of circuit technology, for example wired serially or in parallel to form modules, trains and a battery pack.

According to the disclosure, a motor vehicle having a battery of this type is also made available, wherein the battery is connected to a drive system of the motor vehicle. The method is preferably applied in electrically driven vehicles in which a plurality of battery cells are connected together in order to make available the necessary drive voltage.

The described method extends the storage of use histograms with the result that use of the battery in the last driving cycles is stored in a detailed fashion and the use of the battery in driving cycles lying further back is stored in a combined fashion, i.e. aggregated, and the total use of the battery is stored by means of a histogram which covers the entire service life.

A reduced storage requirement is advantageously made possible since a separate histogram is not stored for each driving cycle but instead a combined version of a plurality of histograms is stored as a function of the age of the histogram. Through aggregation, separate histograms can be stored for individual driving cycles despite a long service life of the battery and storage limitations of the control device. The complete storage of the histograms of the last driving cycles provides the possibility of acquiring very precise information about the last use of the battery, which is of interest particularly in warranty cases. An adapted data structure provides efficient access to the various use histograms. The data structure permits good scalability by virtue of the fact that the number of measurement variables to be detected can be extended as desired. High-dimensional histograms can be used which specify, for example, how long the battery has been used with a specific combination of state of charge, temperature and current flow. Furthermore, the method can be applied in parallel to various independent histograms.

### BRIEF DESCRIPTION OF THE DRAWINGS

Exemplary embodiments of the disclosure are illustrated in the drawings and explained in more detail in the following description.

In the drawings:

FIG. 1 shows an example of a unidimensional histogram,

FIG. 2 shows an example of a two-dimensional histogram,

FIG. 3 shows an illustration of the aggregation of unidimensional histograms,

FIG. 4 shows data structures according to a first embodiment disclosed herein, and

FIG. 5 shows data structures according to a second embodiment disclosed herein.

### DETAILED DESCRIPTION

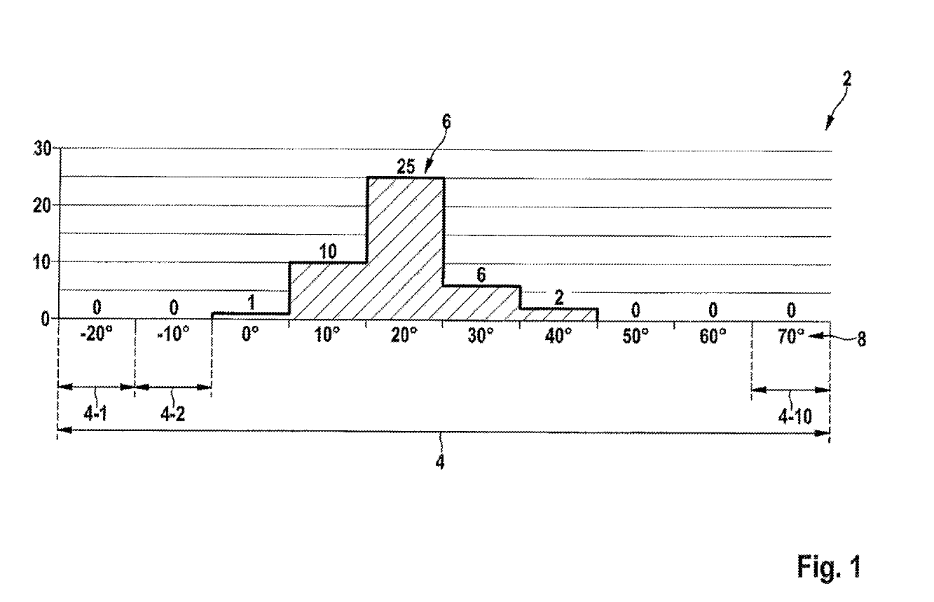

FIG. 1 shows a unidimensional histogram 2 in which frequency values 6 of the occurrence of specific measured values which are illustrated on the ordinate of the histogram 2 are illustrated. The histogram 2 may have been produced during one or more driving cycles of a motor vehicle and shows temperature values 8 of a battery unit which have been detected by way of example.

In the illustrated example, a total interval 4, which comprises here for example temperature values 8 from −20° C. to +70° C., is divided into ten individual intervals 4-1, 4-2, . . . 4-10, wherein the individual intervals 4-1, 4-2, . . . 4-10 here have for example an interval width of 10° C. The temperature values 8 which are specified below the diagram may refer, for example, to the mean values of the values which are given by the interval boundaries or else to the value of the left-hand or the right-hand boundary.

The histogram 2 comprises here, for example, one measurement of the use at 0° C., 10 measurements of the use at 10° C., 25 measurements of the use at 20° C., 6 measurements of the use at 30° C. and 2 measurements of the use at 40° C. The histogram 2 can also be present as a two-dimensional 10-tuple in a suitable computer unit

(0, −20°; 0, −10°; 1, 0°; 10, 10°; 25, 20°; 6, 30°; 2, 40°; 0, 50°; 0, 60°; 0, 70°).

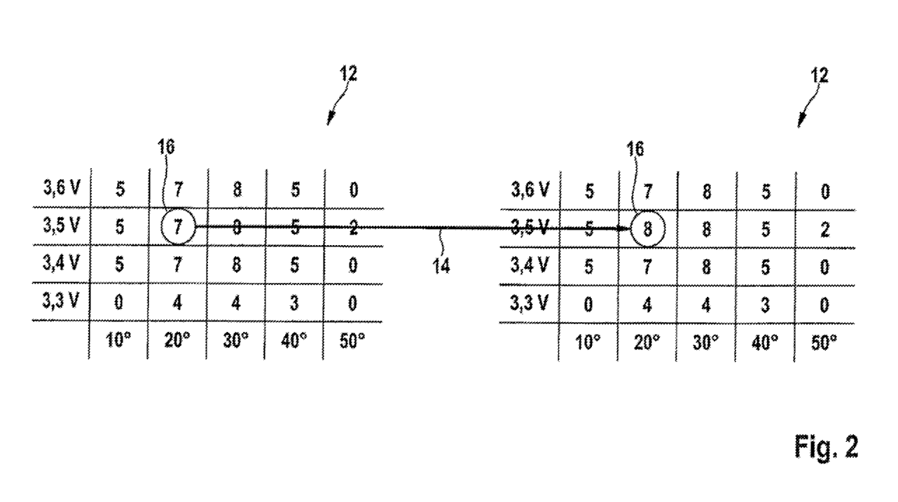

FIG. 2 shows a two-dimensional histogram 12 before and after an updating step 14, which is illustrated here for example as an arrow. The histogram 12 contains, for example, information about the use of a vehicle battery at specific temperatures and voltages. After the updating step 14 it is clear from the histogram 12, for example, that the battery was operated with 8 measurements at 20° C. and a voltage of 3.5 V or else that the battery was not operated at all at 10° C. and 3.3 V.

When the histogram 12 is produced, the temperature and the voltage are determined with a defined detection rate and the corresponding frequency value 16 is increased by 1. In the example, the updating step 14 is illustrated with an increase in the frequency value 16 of the measurement “20°/3.5 volts”.

The histogram 12 from FIG. 2 before the updating step 14 can be present within the computer as a tuple, for example as

(5, 3.6 V, 10°; 7, 3.6 V, 20°; 8, 3.6 V, 30°; 5, 3.6 V, 40°; 0, 3.6 V, 50°; 5, 3.5 V, 10°; 7, 3.5 V, 20°; 8, 3.5 V, 30°; 5, 3.5 V, 40°; 2, 3.5 V, 50°; 5, 3.4 V, 10°; 7, 3.4 V, 20°; 8, 3.4 V, 30°; 5, 3.4 V, 40°; 0, 3.4 V, 50°; 0, 3.3 V, 10°; 4, 3.3 V, 20°; 4, 3.3 V, 30°; 3, 3.3 V, 40°; 0, 3.3 V, 50°)

or correspondingly in another arrangement of the voltage and the temperature.

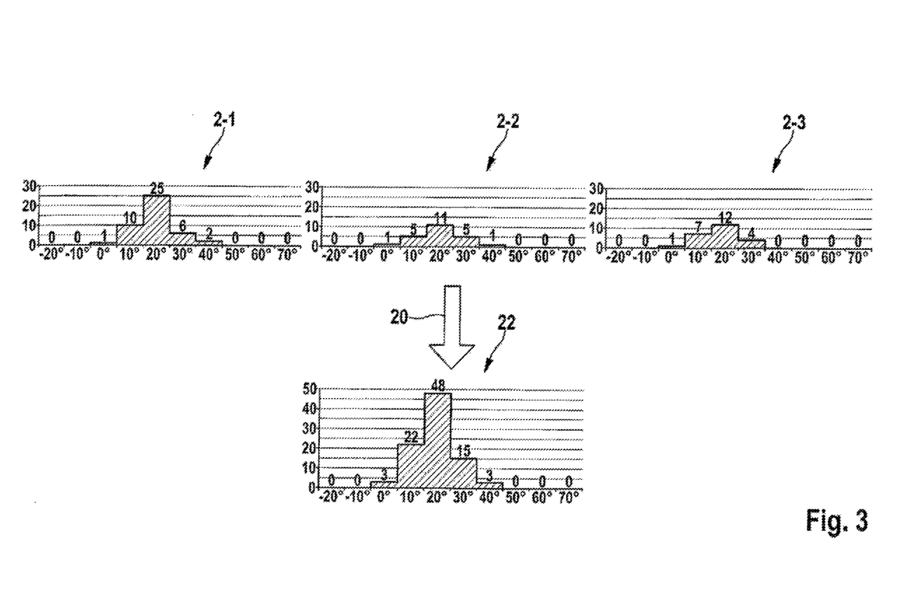

In FIG. 3, an aggregation of histograms is illustrated for example, wherein here for example three histograms 2-1, 2-2, 2-3 are illustrated which have been described with reference to FIG. 1. The three histograms 2-1, 2-2, 2-3, which may be histograms which are themselves already aggregated, are changed into an aggregated histogram 22 in an aggregation step 20, here an addition step. The aggregation described below can correspondingly also be transferred to higher dimensional histograms.

The first histogram 2-1 is present, for example, as a two-dimensional 10-tuple

(0, −20°; 0, −10°; 1, 0°; 10, 10°; 25, 20°; 6, 30°; 2, 40°; 0, 50°; 0, 60°; 0, 70°),

the second histogram 2-2 is present as a two-dimensional 10-tuple

(0, −20°; 0, −10°; 1, 0°; 5, 10°; 11, 20°; 5, 30°; 1, 40°; 0, 50°; 0, 60°; 0, 70°),

and the third histogram 2-3 is present as a two-dimensional 10-tuple

(0, −20°; 0, −10°; 1, 0°; 7, 10°; 12, 20°; 4, 30°; 0, 40°; 0, 50°; 0, 60°; 0, 70°).

By adding the corresponding positions of the tuple an aggregated histogram 22 is formed which can be present as a two-dimensional 10-tuple

(0, −20°; 0, −10°; 3, 0°; 22, 10°; 48, 20°; 15, 30°; 3, 40°; 0, 50°; 0, 60°; 0, 70°).

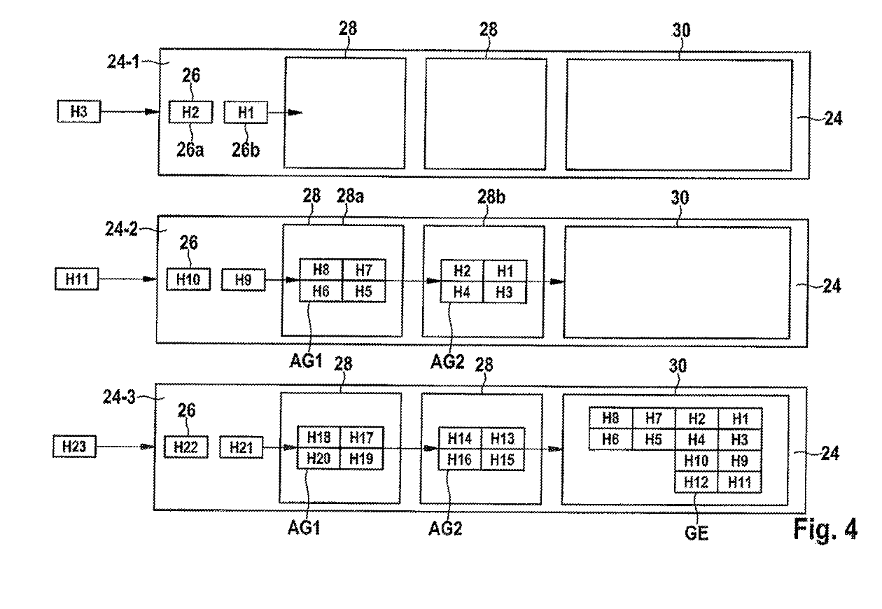

FIG. 4 shows suitable data structures 24 according to a first embodiment of the disclosure. The data structures 24 comprise fields 26 for storing complete histograms, fields 28 for storing aggregated histograms and a field 30 for storing a total histogram. For example, two fields 26a, 26b are provided for storing the complete histograms but there may be as many as desired, depending on the storage capacity. For example, two fields 28a, 28b are also provided for storing the aggregated histograms, but there may be as many as desired, depending on the storage capacity.

In the illustrated example, a first data structure 24-1 contains information about useful data of a battery unit of a motor vehicle after a 2nd driving cycle and is updated with the information about the corresponding useful data of the 3rd driving cycle. The two fields 26a, 26b for storing the complete histograms are filled with a histogram H1 of the 1st driving cycle and a histogram H2 of the 2nd driving cycle. If the histogram H3 of the 3rd driving cycle is taken up, the histogram H1 of the 1st driving cycle is transferred into a field 28 for storing the aggregated histograms, as indicated by an arrow. It is possible to provide that the histogram H2 of the 2nd driving cycle is written to the point at which the histogram H1 of the 1st driving cycle was located, as indicated by a dashed arrow. This behavior corresponds to what is referred to as a data stack. The histogram H3 of the 3rd driving cycle can either take up the location 26 at which the histogram H1 of the 1st driving cycle was located after the 2nd driving cycle or the location 26 at which the histogram H2 of the 2nd driving cycle was located after the 2nd driving cycle.

As a result, in the first data structure 24-1 the histograms H1 and H2 of the first two driving cycles are firstly stored completely. After the 3rd driving cycle, which has generated the histogram H3, an overflow of the completely stored histogram occurs with the result that the histograms H2 and H3 are stored completely and the histogram H1 is added to the first aggregated histogram AG1. The first aggregated histogram is composed only of H1 at this time. After the 4th driving cycle, an overflow takes place again with the result that H3 and H4 are stored completely and H2 is added to the first aggregated histogram AG1. The histogram entries from H2 are added here to the entries in AG1. AG1 is composed of the sum of H1 and H2.

A second data structure 24-2 is illustrated after 10 driving cycles, wherein an 11th histogram H11 is added. The memory locations 28a, 28b of the aggregated histograms are filled with aggregated histograms AG1, AG2 of the first 8 driving cycles and the memory locations 26a, 26b for the detailed driving cycles are filled with the histograms H9, H10 for the 9th and 10th driving cycles. If the histogram H11 is then stored for the 11th driving cycle in the data structure 24-2, an aggregated histogram AG2, which comprises the histograms of the first 4 driving cycles, is shifted into the memory location 30 of the total histogram. The aggregated histogram AG1, which comprises the histograms H5-H8 of the driving cycles 5-8, can, for example, be transferred into the lower memory location 28b in order to provide space in the higher memory location 28a for the histogram H9, still present in detailed form, of the 9th driving cycle, or the histogram H9 is stored at the lower location 28b. The re-occupation of the memory locations 26b, 26a which are present in detailed form can be carried out as described with reference to the data structure 24-1.

A third data structure 24-3 is illustrated after 22 driving cycles. The memory location 30 for the total histogram is occupied by a total histogram GE, which was generated by aggregation of the histograms H1-H12 of the first 12 driving cycles. The memory locations 28a, 28b of the aggregated histograms are occupied by the aggregated histograms AG1, AG2 of the driving cycles 13-16 and 17-20, and the memory locations 26a, 26b for the detailed driving cycle values are occupied by the histograms H21, H22 of the driving cycles 21 and 22.

A detailed exemplary embodiment can be found in the following table:

| | Histogram | Completely | | Aggregated | Aggregated | Total |
|---|---|---|---|---|---|---|
| Driving | formed from | stored | | histogram 1 | histogram 2 | histogram |
| cycle | driving cycle | histograms | | AG1 | AG2 | GE |
| 1 | H1 | H1 | | | | |
| 2 | H2 | H1 | H2 | | | |
| 3 | H3 | H2 | H3 | Σ(H1) | | |
| 4 | H4 | H3 | H4 | Σ(H1-H2) | | |
| 5 | H5 | H4 | H5 | Σ(H1-H3) | | |
| 6 | H6 | H5 | H6 | Σ(H1-H4) | | |
| 7 | H7 | H6 | H7 | Σ(H5) | Σ(H1-H4) | |
| 8 | H8 | H7 | H8 | Σ(H5-H6) | Σ(H1-H4) | |
| 9 | H9 | H8 | H9 | Σ(H5-H7) | Σ(H1-H4) | |
| 10 | H10 | H9 | H10 | Σ(H5-H8) | Σ(H1-H4) | |
| 11 | H11 | H10 | H11 | Σ(H9) | Σ(H5-H8) | Σ(H1-H4) |
| 12 | H12 | H11 | H12 | Σ(H9-H10) | Σ(H5-H8) | Σ(H1-H4) |
| 13 | H13 | H12 | H13 | Σ(H9-H11) | Σ(H5-H8) | Σ(H1-H4) |
| 14 | H14 | H13 | H14 | Σ(H9-H12) | Σ(H5-H8) | Σ(H1-H4) |
| 15 | H15 | H14 | H15 | Σ(H13) | Σ(H9-H12) | Σ(H1-H8) |
| 16 | H16 | H15 | H16 | Σ(H13-H14) | Σ(H9-H12) | Σ(H1-H8) |
| 17 | H17 | H16 | H17 | Σ(H13-H15) | Σ(H9-H12) | Σ(H1-H8) |
| 18 | H18 | H17 | H18 | Σ(H13-H16) | Σ(H9-H12) | Σ(H1-H8) |
| 19 | H19 | H18 | H19 | Σ(H17) | Σ(H13-H16) | Σ(H1-H12) |
| 20 | H20 | H19 | H20 | Σ(H17-H18) | Σ(H13-H16) | Σ(H1-H12) |
| 21 | H21 | H20 | H21 | Σ(H17-H19) | Σ(H13-H16) | Σ(H1-H12) |
| 22 | H22 | H21 | H22 | Σ(H17-H20) | Σ(H13-H16) | Σ(H1-H12) |
| . . . | . . . | . . . | . . . | . . . | . . . | . . . |

Examples of analyses of histograms:

After driving cycle 15: the driving cycles 14 and 15 are present at a level of full detail. Driving cycle 13 is also completely present since the histogram H13 is the only histogram in the first aggregated histogram AG1. Driving cycles 9 to 12 are present in a combined form in the second aggregated histogram AG2. Driving cycles 1 to 8 are present as a combined total histogram GE.

After driving cycle 22: the driving cycles 21 and 22 are present at a level of full detail. Driving cycles 17 to 20 are present in a combined form in the first aggregated histogram AG1. Driving cycles 13 to 16 are present in a combined form in the second aggregated histogram AG2. Driving cycles 1 to 12 are present as a combined total histogram GE.

In practice, the method can be carried out, for example, as follows: during the driving cycle a current histogram is produced in the volatile memory, for example RAM, of the control device, wherein the updating steps can take place as described with reference to FIG. 2. After the driving cycle, the data structure 24 is loaded from a non-volatile memory, for example EEPROM, into the volatile memory, updated with the current histogram as described with reference to FIG. 4 and written again into the non-volatile memory of the control device, i.e., stored. If the maximum number of histograms to be stored completely is exceeded, a first aggregated histogram is formed, as described with reference to FIG. 3. If the level of aggregation is reached, the aggregated histogram is complete. The aggregated histogram is stored and stored together with the other aggregated histograms. If the maximum number of aggregated histograms is exceeded, the oldest aggregated histogram is added to the total histogram. The total histogram is likewise formed by aggregation, as described with reference to FIG. 3, here by aggregation of aggregated histograms. As a result, each stored histogram is firstly stored completely in the following driving cycles, then stored in an aggregated form in the further driving cycles and finally added to the total histogram in the further course of the process.

In the example described with respect to FIG. 4, a total of 5 histograms are stored: 1 total histogram, 2 aggregated histograms and 2 complete histograms from the last two driving cycles. Through multi-stage aggregation the method can be adapted further to the requirements. The data structure can have the designators num_aggHisto, grad_aggHisto and num_vollstHisto, which specify the number and aggregation level of aggregated histograms and the number of complete histograms.

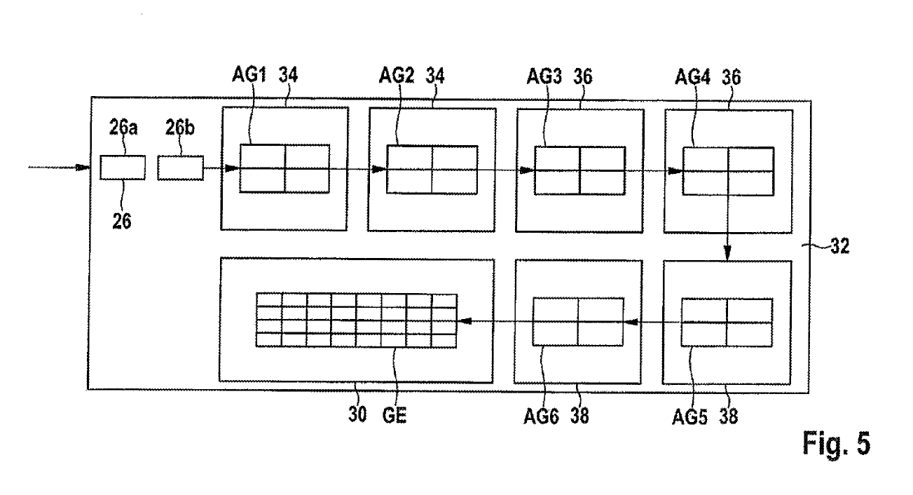

FIG. 5 shows, for example, a data structure 32 according to a further exemplary embodiment with 9 histograms. Histograms of the first aggregation level AG1, AG2 occupy memory locations 34. Histograms AG3, AG4 of the second aggregation level occupy memory locations 36, histograms AG5, AG6 of the third aggregation level occupy memory locations 38, and a total histogram GE of the highest aggregation level occupies a memory location 30.

The number of histograms to be stored in total can be changed by changing the parameters num_aggHisto, grad_aggHisto and num_vollstHisto.

Total of histograms to be stored=num_aggHisto+num_vollstHisto+1.

After each driving cycle, the number num_vollstHisto of complete histograms is stored at the memory locations 26 and num_aggHisto_1 histograms with the aggregation level grad_aggHisto_1 are formed and stored at the memory locations 34. The latter therefore contain the sum of max. grad_aggHisto_1 histograms. Furthermore, num_aggHisto_2 histograms with the aggregation level grad_aggHisto_2 are formed and stored at the memory locations 36. The latter therefore contain the sum of max. grad_aggHisto_2 aggregated histograms from the previous aggregation level. Furthermore, num_aggHisto_3 histograms with the aggregation level grad_aggHisto_3 are formed and stored at the memory locations 38. The latter therefore contain the sum of max. grad_aggHisto_3 aggregated histograms from the previous aggregation level. The oldest driving cycles are present in a combined form in the total histogram GE.

The disclosure is not restricted to the exemplary embodiments described here and the aspects highlighted therein. Rather, within the field specified herein, a multiplicity of refinements lying within the scope of the ability of a person skilled in the art are possible.

What is claimed is:

1. A method for making available information for the purpose of performing maintenance and servicing of a battery unit comprising:
detecting and quantizing useful data of a battery unit;
generating histograms which have frequencies of the occurrence of specific values of the individual quantized useful data items or values derived therefrom; and
storing at least one current histogram and at least one aggregated histogram in a non-volatile memory.

2. The method according to claim 1, wherein the histograms are generated and stored after each driving cycle.

3. The method according to claim 1, wherein the at least one aggregated histogram has an aggregation level of between 2 and 10 driving cycles.

4. The method according to claim 1, further comprising:
generating a total histogram.

5. The method according to claim 1, the detection of the useful data further comprising:
detecting the useful data with a detection rate having a defined value between 6 per second and 6 per hour.

6. The method according to claim 1, wherein the useful data of the battery includes one selected from the group consisting of a temperature, a state of charge, a current which is output, and a voltage which is made available.

7. The method according to claim 1, wherein the histograms are stored in a stack data structure.

8. A data structure with information on conditions of use of a battery, wherein the data structure is produced during the execution the method according to claim 1, and wherein the data structure is configured to be read by a computer device for the purpose of performing maintenance and servicing.

9. A programmable computer device comprising:
a memory; and
a processor configured to execute a computer program stored in the memory to implement the method according to claim 1.

10. A battery management system comprising:
a detecting unit configured to detect useful data of a battery unit;
a quantizing unit configured to quantize the detected useful data; and
a histogram unit configured to generate at least one current histogram and at least one aggregated histogram from histograms,
wherein the histograms have frequencies of the occurrence of specific values of the individual useful data items or values derived therefrom.

11. A battery comprising:
a plurality of battery cells; and
a battery management system including (i) a detecting unit configured to detect useful data of the battery, (ii) a quantizing unit configured to quantize the detected useful data, and (iii) a histogram unit configured to generate at least one current histogram and at least one aggregated histogram from histograms,
wherein the histograms have frequencies of the occurrence of specific values of the individual useful data items or values derived therefrom, and
wherein the battery is configured to be connected to a drive system of a motor vehicle.

12. A motor vehicle comprising:
a drive system of the motor vehicle; and
the battery according to claim 11.
